(19) United States
(12) Patent Application Publication
(10) Pub. No.: US 2026/0164981 A1
(43) Pub. Date: Jun. 11, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-si (KR)

(72) Inventors: Suk KIM, Yongin-si (KR); Gun Hee KIM, Yongin-si (KR); Hyoung Wook JANG, Yongin-si (KR); Jae Kyoung KIM, Yongin-si (KR)

(21) Appl. No.: 19/179,680

(22) Filed: Apr. 15, 2025

(30) Foreign Application Priority Data
Jun. 21, 2024 (KR) 10-2024-0081227
Aug. 6, 2024 (KR) 10-2024-0104896

(51) Int. Cl. H10K 59/60; H10K 59/12; H10K 59/122; H10K 59/80

(52) U.S. Cl. CPC H10K 59/60; H10K 59/1201; H10K 59/122; H10K 59/80522

(57) ABSTRACT

A display device includes a substrate including a region where a first sub-pixel and a second sub-pixel are formed; a lower electrode layer on the substrate; a light sensing element on the lower electrode layer of the first sub-pixel; a first intermediate electrode layer on the light sensing element; a first light emitting element on the first intermediate electrode layer; and a first upper electrode layer on the first light emitting element, wherein the first light emitting element and the light sensing element are individually driven according to a voltage applied to the first intermediate electrode layer.

### CROSS-REFERENCE TO RELATED APPLICATION

The present application claims priority to and the benefit of Korean Patent Application No. 10-2024-0081227, filed on Jun. 21, 2024, and Korean Patent Application No. 10-2024-0104896, filed on Aug. 6, 2024, in the Korean Intellectual Property Office, the entire disclosure of which are incorporated herein by reference.

### BACKGROUND

### 1. Field

Aspects of the present disclosure relate to a display device, a method of manufacturing the display device, and electronic device including the display device.

### 2. Description of the Related Art

As interest in information display has been increased recently, research and development on display devices have been continuously conducted.

The above description is only intended to help understand the background technology for technical ideas of the present disclosure, and therefore, the above description may not be understood as description corresponding to the known technology to those skilled in the art to which the present disclosure belongs.

### SUMMARY

Aspects of embodiments of the present disclosure are directed to a display device with improved resolution and a method of manufacturing the display device.

According to some embodiments of the present disclosure, there is provided a display device including: a substrate including a region where a first sub-pixel and a second sub-pixel are formed; a lower electrode layer on the substrate; a light sensing element on the lower electrode layer of the first sub-pixel; a first intermediate electrode layer on the light sensing element; a first light emitting element on the first intermediate electrode layer; and a first upper electrode layer on the first light emitting element, wherein the first light emitting element and the light sensing element are individually driven according to a voltage applied to the first intermediate electrode layer.

In some embodiments, the light sensing element is not driven in a period in which the first light emitting element emits light.

In some embodiments, the display device further includes: a second intermediate electrode layer on the lower electrode layer of the second sub-pixel; a second light emitting element on the second intermediate electrode layer; and a second upper electrode layer on the second light emitting element, wherein the second light emitting element emits different light from the first light emitting element.

In some embodiments, the display device further includes: first pixel defining layers and second pixel defining layers on the substrate and protruding in a direction perpendicular to the substrate, wherein the first intermediate electrode layer is physically separated from the second intermediate electrode layer by the first pixel defining layers, and wherein the first upper electrode layer is physically separated from the second upper electrode layer by the first pixel defining layers.

In some embodiments, the first pixel defining layers have different shapes from the second pixel defining layers.

In some embodiments, each of the second pixel defining layers has a cross-section of a trapezoidal shape.

In some embodiments, each of the first pixel defining layers has an eleventh pixel defining layer and a twelfth pixel defining layer coupled to each other in a form perpendicular to the substrate, the eleventh pixel defining layer has a cross-section of a trapezoidal shape, and the twelfth pixel defining layer has a cross-section of an inverted trapezoidal shape.

In some embodiments, the display device further includes: upper auxiliary electrode layers on the first upper electrode layer and the second upper electrode layer, wherein the upper auxiliary electrode layer on the first upper electrode layer is physically connected to the upper auxiliary electrode layer on the second upper electrode layer.

In some embodiments, a second power supply voltage is applied to the lower electrode layer, a first power supply voltage is applied to each of the first upper electrode layer and the second upper electrode layer, and a level of the first power supply voltage is higher than a level of the second power supply voltage.

According to some embodiments of the present disclosure, there is provided an electronic device including the display device as described above.

In some embodiments, the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

According to some embodiments of the present disclosure, there is provided a method of manufacturing a display device, the method including: forming a substrate including a region where a first sub-pixel and a second sub-pixel are formed; forming a lower electrode layer on the substrate; forming a light sensing element on the lower electrode layer of the first sub-pixel; forming a first intermediate electrode layer on the light sensing element; forming a first light emitting element on the first intermediate electrode layer; and forming a first upper electrode layer on the first light emitting element, wherein the first light emitting element and the light sensing element are individually driven according to a voltage applied to the first intermediate electrode layer.

In some embodiments, the light sensing element is not driven in a period in which the first light emitting element emits light.

In some embodiments, the method further includes: forming a second intermediate electrode layer on the lower electrode layer of the second sub-pixel; forming a second light emitting element on the second intermediate electrode layer; and forming a second upper electrode layer on the second light emitting element.

In some embodiments, the method further includes: forming, on the substrate, first pixel defining layers and second pixel defining layers protruding in a direction perpendicular to the substrate, wherein the first intermediate electrode layer is physically separated from the second intermediate electrode layer by the first pixel defining layers, and wherein the first upper electrode layer is physically separated from the second upper electrode layer by the first pixel defining layers.

In some embodiments, the first pixel defining layers have different shapes from the second pixel defining layers.

In some embodiments, each of the second pixel defining layers has a cross-section of a trapezoidal shape.

In some embodiments, each of the first pixel defining layers has an eleventh pixel defining layer and a twelfth pixel defining layer coupled to each other in a form perpendicular to the substrate, the eleventh pixel defining layer has a cross-section of a trapezoidal shape, and the twelfth pixel defining layer has a cross-section of an inverted trapezoidal shape.

In some embodiments, the method further includes: forming upper auxiliary electrode layers respectively on the first upper electrode layer and the second upper electrode layer, wherein the upper auxiliary electrode layer on the first upper electrode layer is physically connected to the upper auxiliary electrode layer on the second upper electrode layer.

In some embodiments, a second power supply voltage is applied to the lower electrode layer, a first power supply voltage is applied to each of the first upper electrode layer and the second upper electrode layer, and a level of the first power supply voltage is higher than a level of the second power supply voltage.

Accordingly, the present disclosure may provide a display device with improved resolution and a method of manufacturing the display device.

Effects according to some embodiments are not limited to the above descriptions, and more diverse effects are included in the present disclosure.

### BRIEF DESCRIPTION OF THE DRAWINGS

FIG. 1 is a block diagram illustrating a display device according to some embodiments of the present disclosure.

FIG. 2 is a plan view of the display panel of FIG. 1, according to some embodiments of the present disclosure.

FIG. 3 is an enlarged view of a portion X of FIG. 2, according to some embodiments of the present disclosure.

FIG. 4 is a cross-sectional view taken along the line I-I′ of FIG. 3, according to some embodiments of the present disclosure.

FIG. 5 is a view illustrating a first pixel defining layer of FIG. 4, according to some embodiments of the present disclosure.

FIG. 6 is a flowchart illustrating a method of manufacturing a display device, according to some embodiments of the present disclosure.

FIG. 7 is a view illustrating the process of forming the substrate and the circuit element layer as described in FIG. 6, according to some embodiments of the present disclosure.

FIG. 8 is a view illustrating the process of forming the first and second pixel defining layers and lower electrode layer as described with reference to FIG. 6, according to some embodiments of the present disclosure.

FIG. 9 is a view illustrating the process of forming a light sensing element as described with reference to FIG. 6, according to some embodiments of the present disclosure.

FIG. 10 is a view illustrating the process of forming an intermediate layer as described with reference to FIG. 6, according to some embodiments of the present disclosure.

FIG. 11 is a view illustrating the process of forming the first to third light emitting elements as described with reference to FIG. 6, according to some embodiments of the present disclosure.

FIG. 12 is a view illustrating the process of forming the upper electrode layer as described with reference to FIG. 6, according to some embodiments of the present disclosure.

FIG. 13 is a view illustrating the process of forming the upper auxiliary electrode layer as described with reference to FIG. 6, according to some embodiments of the present disclosure.

FIG. 14 is a block diagram of an electronic device according to some embodiments of the present disclosure.

FIG. 15 shows schematic views of various embodiments of an electronic device, according to some embodiments of the present disclosure.

### DETAILED DESCRIPTION

Hereinafter, some embodiments of the present disclosure will be described in detail with reference to the attached drawings. In the following description, only the parts necessary for understanding an operation of the present disclosure may be described, and it should be noted that the description of the other parts will be omitted so as not to obscure the gist of the present disclosure. In addition, the present disclosure is not limited to the embodiments described herein and may also be embodied in other forms. However, embodiments described herein are provided to explain the technical idea of the present disclosure in detail to a degree that a person having ordinary knowledge in the technical field to which the present disclosure belongs may easily practice the embodiments.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Various embodiments are described with reference to drawings illustrating idealized embodiments. Accordingly, it will be expected that the shapes may change depending on, for example, tolerances and/or manufacturing techniques. Accordingly, embodiments disclosed herein should not be construed as being limited to the illustrated specific shapes but should be construed to include, for example, changes in shapes resulting from manufacturing. As such, the shapes illustrated in the drawings may not illustrate actual shapes of regions of the device, and the present embodiments are not limited thereto.

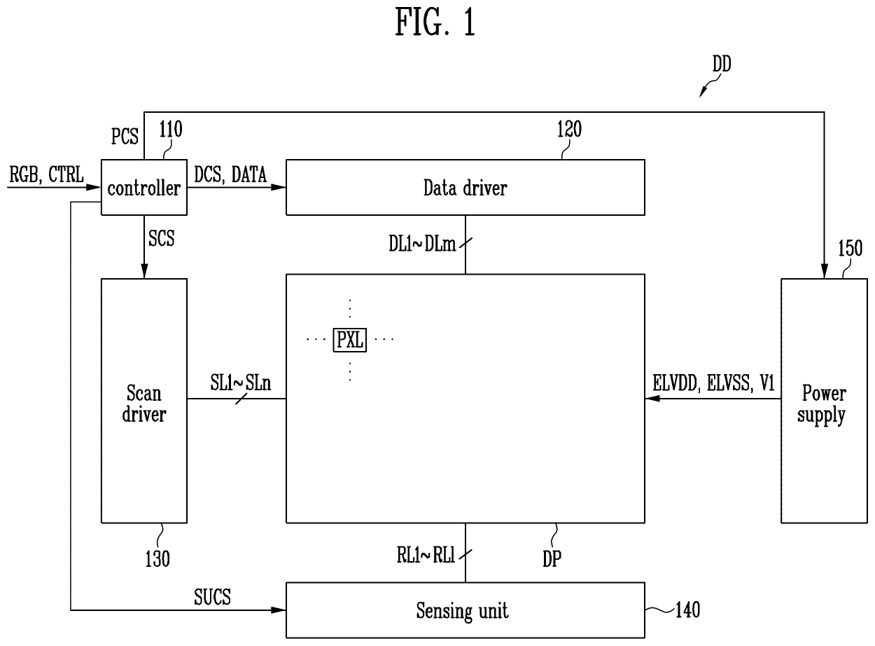

FIG. 1 is a block diagram illustrating a display device according to some embodiments of the present disclosure.

Referring to FIG. 1, a display device DD may include a display panel DP, a controller 110, a data driver 120, a scan driver 130, a sensing unit 140, and a power supply 150.

The display panel DP may include a plurality of pixels PXL. The display panel DP may be connected to data lines DL1 to DLm, scan lines SL1 to SLn, and sensing lines RL1 to RLl. In the display panel DP, the plurality of pixels PXL may be electrically connected to the data lines DL1 to DLm, scan lines SL1 to SLn, and sensing lines RL1 to RLl.

The display panel DP may be one of panels of various types, such as an organic light emitting diode (OLED) panel. The type of wires disposed in the display panel DP may change depending on a pixel structure, a panel type, and/or the like.

The controller 110 may control operations of the data driver 120, the scan driver 130, the sensing unit 140, and the power supply 150. The controller 110 may provide a first control signal SCS to the scan driver 130 to apply a scan signal to the scan lines SL1 to SLn according to the timing implemented in each frame. The controller 110 may provide an image data signal DATA obtained by converting a data format of an image signal in accordance with an interface specification of the data driver 120. When the scan signal is applied to the scan lines SL1 to SLn, the controller 110 may provide a second control signal DCS to the data driver 120 such that data voltages are applied to the data lines DL1 to DLm. The controller 110 may provide a third control signal SUCS to the sensing unit 140 such that the sensing unit 140 may perform a sensing operation by using the sensing lines RL1 to RLl. In addition, the controller 110 may provide a fourth control signal PCS to the power supply 150.

The controller 110 may be a timing controller used in a display technology of the related art, and may also be a control device that may perform other control functions by including a timing controller.

The data driver 120 may output data signals to the data lines DL1 to DLm. For example, the data driver 120 may receive the second control signal DCS and the image data signal DATA from the controller 110. The data driver 120 may convert the image data signal DATA into data signals and output the data signals to the data lines DL1 to DLm. Here, the data signals may be analog voltages corresponding to grayscale values of the image data signal DATA. That is, when a certain scan line is selected by the scan driver 130, the data driver 120 may supply analog data voltages to the data lines DL1 to DLm.

The scan driver 130 may receive the first control signal SCS from the controller 110. The scan driver 130 may output a scan signal to the scan lines SL1 to SLn. The scan driver 130 may sequentially supply scan signals to the scan lines SL1 to SLn according to the first control signal SCS from the controller 110. The plurality of pixels PXL receiving the scan signals may receive analog voltages having grayscale values corresponding to the image data signal DATA and output light of brightness corresponding to the received analog voltages in response to a light emission control signal. Accordingly, an image may be displayed on the display panel DP.

Although FIG. 1 illustrates that the data driver 120 and the scan driver 130 are separate components for the sake of convenience of description, the present disclosure is not limited thereto. That is, at least a part of the data driver 120 and the scan driver 130 may be integrated into one drive circuit, module, or the like.

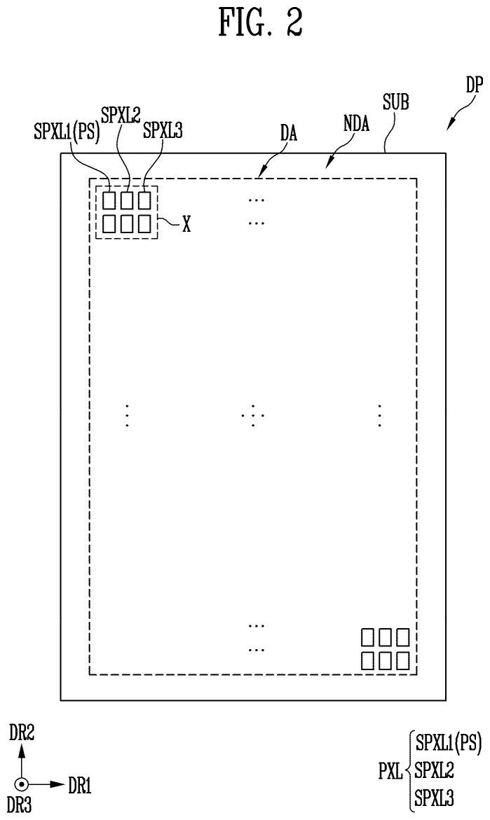

The sensing unit 140 may receive the third control signal SUCS from the controller 110. The sensing unit 140 may detect a current (or an electrical signal) transmitted from an optical sensor PS (see, e.g., FIG. 2) through the sensing lines RL1 to RL1 in response to the third control signal SUCS. The sensing unit 140 may detect a touch on the display panel DP or recognize a fingerprint on the display panel DP by using the current (or the electrical signal).

The power supply 150 may receive the fourth control signal PCS from the controller 110. The power supply 150 may supply voltages (e.g., a first power supply voltage ELVDD, a second power supply voltage ELVSS, a first voltage V1, and/or the like) to the display panel DP in response to the fourth control signal PCS. In some embodiments, the first power supply voltage ELVDD may be a higher voltage than the second power supply voltage ELVSS.

FIG. 2 is a plan view of the display panel DP of FIG. 1, according to some embodiments of the present disclosure.

Referring to FIG. 2, the display panel DP and a substrate SUB for forming the display panel DP may include a display region DA for displaying an image, and a non-display region NDA excluding the display region DA. The display region DA may constitute a screen on which an image is displayed, and the non-display region NDA may be the other region excluding the display region DA.

For the sake of convenience of description, a structure of the display panel DP is briefly illustrated in FIG. 2 by focusing on the display region DA. However, at least one drive circuit (e.g., at least one of a scan driver, a data driver, or a sensing unit), wires, and/or pads may be further arranged on the display panel DP.

The plurality of pixels PXL may be arranged on the display region DA. Each of the plurality of pixels PXL may include a first sub-pixel SPXL1, a second sub-pixel SPXL2, a third sub-pixel SPXL3, and the light sensor PS. For the sake of clear and concise description, FIG. 2 illustrates the first sub-pixel SPXL1, the second sub-pixel SPXL2, the third sub-pixel SPXL3, and the light sensor PS included in one pixel. It may be understood that each of the other pixels also includes the first sub-pixel SPXL1, the second sub-pixel SPXL2, the third sub-pixel SPXL3, and the light sensor PS.

The plurality of pixels PXL may be arranged regularly according to a stripe arrangement structure, a PENTILE™ arrangement structure, or the like. However, the arrangement structures of the plurality of pixels PXL are not limited thereto, and the plurality of pixels PXL may be arranged in the display region DA in various suitable structures and/or methods.

The first sub-pixel SPXL1 emitting light of a first color, the second sub-pixel SPXL2 emitting light of a second color, and the third sub-pixel SPXL3 emitting light of a third color may be arranged in the display region DA. At least one of the first, second, and third sub-pixels SPXL1, SPXL2, and SPXL3 arranged adjacent to each other may constitute one pixel capable of emitting light of one of various colors. For example, the first sub-pixel SPXL1 may be a red pixel that emits red light, the second sub-pixel SPXL2 may be a green pixel that emits green light, and the third sub-pixel SPXL3 may be a blue pixel that emits blue light, but the present disclosure is not limited thereto.

However, although FIG. 2 illustrates one first sub-pixel SPXL1, one second sub-pixel SPXL2, and one third sub-pixel SPXL3 that constitute a pixel, the present disclosure is not limited thereto. For example, one of the plurality of pixels PXL may include one first sub-pixel SPXL1, two second sub-pixels SPXL2, and one third sub-pixel SPXL3.

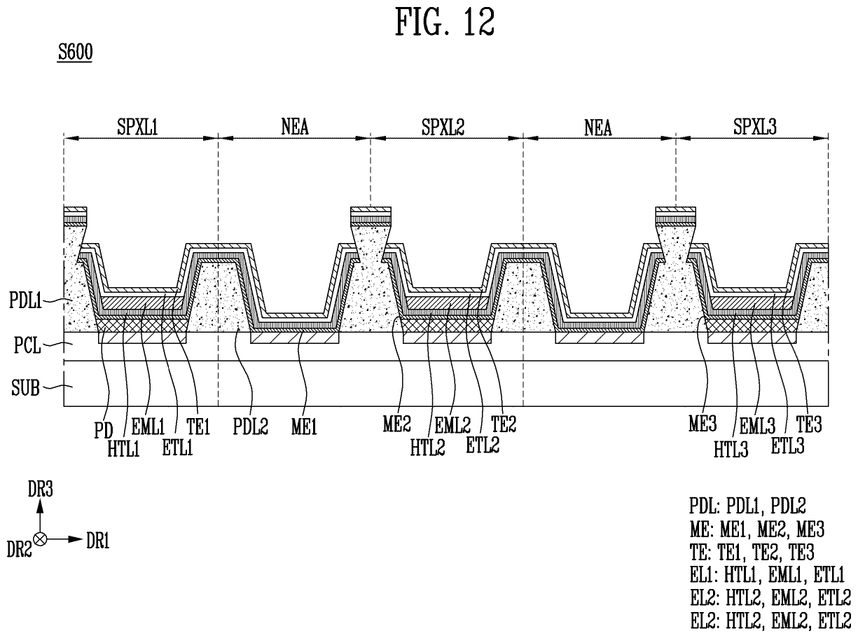

The first sub-pixel SPXL1, the second sub-pixel SPXL2, and the third sub-pixel SPXL3 may each include a light emitting element functioning as a light source. For example, the first sub-pixel SPXL1 may include a first light emitting element EL1 (see, e.g., FIG. 12) functioning as a light source. The second sub-pixel SPXL2 may include a second light emitting element EL2 (see, e.g., FIG. 12) functioning as a light source. The third sub-pixel SPXL3 may include a third light emitting element EL3 (see, e.g., FIG. 12) functioning as a light source. However, the color of light emitted from each of the first to third sub-pixels SPXL1 to SPXL3 may be variously changed.

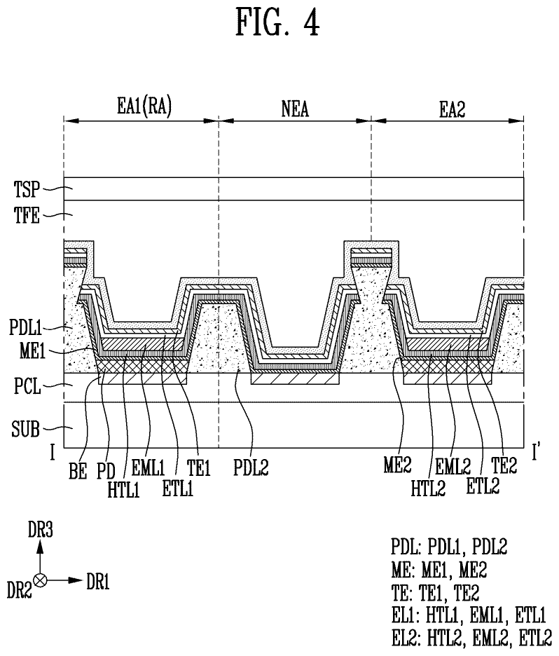

The light sensor PS may include a light sensing element PD (see, e.g., FIG. 4) and drive circuits for driving the light sensing element PD. Here, the drive circuits may be included in a circuit element layer PCL (see, e.g., FIG. 4). The light sensing element PD may be a photoelectric conversion element that converts externally incident light into an electrical signal. The electrical signal generated by the light sensing element PD may be transmitted to the sensing unit 140 (see, e.g., FIG. 1) through the sensing lines RL1 to RL1 (see, e.g., FIG. 1).

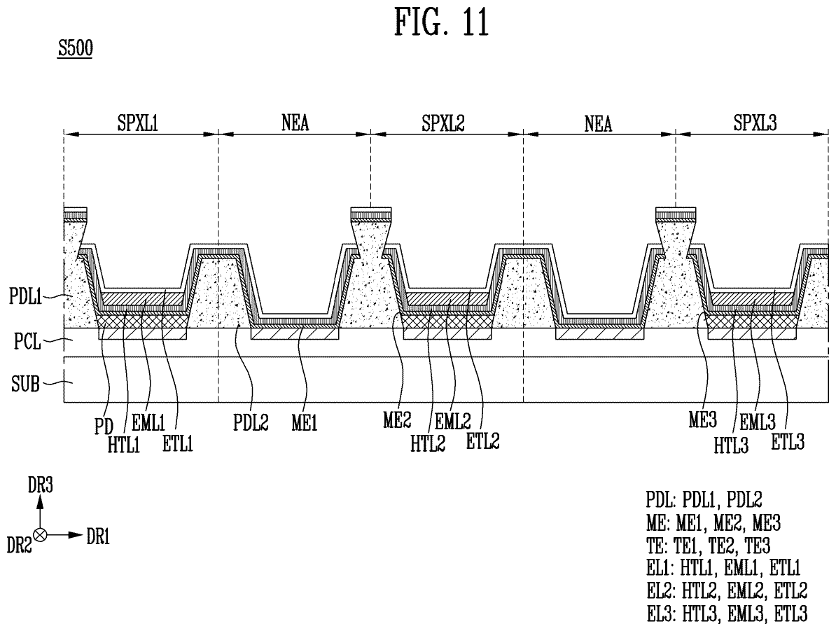

In some embodiments of the present disclosure, the light sensing element PD may overlap any one of first, second, and third light emitting elements EL1, EL2, and EL3 (see, e.g., FIG. 11). For example, the light sensing element PD may overlap the first light emitting element EL1 in a third direction DR3. For example, the light sensing element PD may overlap the second light emitting element EL2 in the third direction DR3. For example, the light sensing element PD may overlap the third light emitting element EL3 in the third direction DR3. As the light sensing element PD overlaps any one of the first to third light emitting elements EL1 to EL3, spatial efficiency may be obtained. In addition, more of the first to third light emitting elements EL1 to EL3 per unit area may be arranged on the display panel DP. Accordingly, resolution of the display panel DP may be increased.

Hereinafter, it is assumed that the light sensing element PD overlaps the first light emitting element EL1.

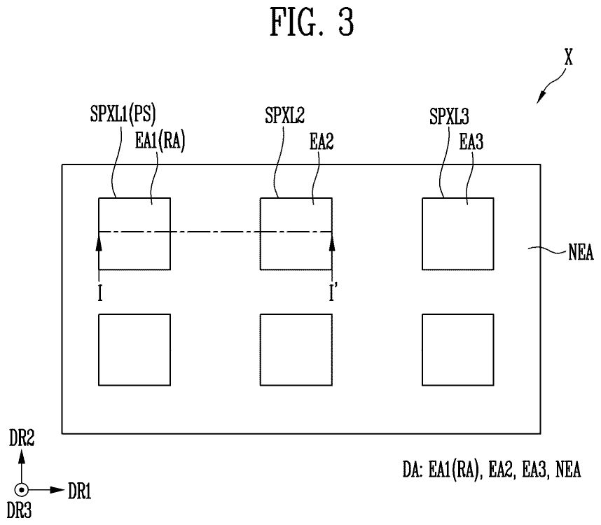

FIG. 3 is an enlarged view of a portion X of FIG. 2, according to some embodiments of the present disclosure.

Referring to FIG. 2 and FIG. 3, the display region DA may include a first light emitting region EA1, a second light emitting region EA2, a third light emitting region EA3, and a non-light emitting region NEA. In some embodiments, when the light sensing element PD overlaps the first light emitting element EL1, a sensing region RA may be included in the first light emitting region EA1.

The first light emitting region EA1 may be a region where light is emitted by the first sub-pixel SPXL1. The second light emitting region EA2 may be a region where light is emitted by the second sub-pixel SPXL2. The third light emitting region EA3 may be a region where light is emitted by the third sub-pixel SPXL3.

The sensing region RA may be a region where a touch on the display panel DP is detected by the light sensor PS (or, the light sensing element PD) or a fingerprint on the display panel DP is recognized.

The non-light emitting region NEA may be a region where the first to third sub-pixels SPXL1 to SPXL3 are not arranged on the display region DA. Therefore, the non-light emitting region NEA may be a region where light is not emitted (e.g., a region not capable of emitting light).

FIG. 4 is a cross-sectional view taken along the line I-I′ of FIG. 3, according to some embodiments of the present disclosure.

Referring to FIG. 4, the display panel DP may include the substrate SUB, the circuit element layer PCL, pixel defining layers PDL, a lower electrode layer BE, the light sensing element PD, an intermediate electrode layer ME, the first light emitting element EL1, the second light emitting element EL2, an upper electrode layer TE, an upper auxiliary electrode layer TAE, an encapsulation layer TFE, and a touch sensing panel TSP.

The pixel defining layers PDL may include first pixel defining layers PDL1 and second pixel defining layers PDL2. The intermediate electrode layer ME may include a first intermediate electrode layer ME1 and a second intermediate electrode layer ME2.

The first light emitting element EL1 may include a first hole transfer layer HTL1, a first light emitting layer EML1, and a first electron transfer layer ETL1. The second light emitting element EL2 may include a second hole transfer layer HTL2, a second light emitting layer EML2, and a second electron transfer layer ETL2.

The upper electrode layer TE may include a first upper electrode layer TE1 and a second upper electrode layer TE2.

The substrate SUB may include a semiconductor substrate. The substrate SUB may have a three-dimensional shape extending in the first to third directions DR1 to DR3. For example, the substrate SUB may include a silicon bulk wafer, an epitaxial wafer, or the like. The epitaxial wafer may include a crystalline material layer, that is, an epitaxial layer, grown on a bulk substrate through an epitaxial process. The substrate SUB may be formed by using various wafers, such as a polished wafer, annealed wafer, and silicon on insulator (SOI) wafer without being limited to the bulk wafer or the epitaxial wafer.

The circuit element layer PCL may be disposed on the substrate SUB. The circuit element layer PCL may have a three-dimensional shape extending in the first to third directions DR1 to DR3. The circuit element layer PCL may include the first and second light emitting elements EL1 and EL2, circuit elements for driving the light sensing element PD, and at least one insulating layer between the circuit elements. The circuit elements may include a plurality of transistors and signal lines connected to the plurality of transistors. For example, the transistors may each be a metal oxide semiconductor field effect transistor (MOSFET) but are not limited thereto. In addition, the circuit elements may each include a gate electrode, source/drain regions, and a channel region.

The substrate SUB and the circuit element layer PCL may be formed by using a semiconductor process and equipment but are not limited thereto.

The substrate SUB and the circuit element layer PCL may be formed in the first light emitting region EA1, the non-light emitting region NEA, and the second light emitting region EA2.

The pixel defining layers PDL and the lower electrode layer BE may be formed on the circuit element layer PCL.

The pixel defining layers PDL may be composed of an organic insulating layer including an organic material. The organic material may include an acrylic resin, an epoxy resin, a phenolic resin, a polyamide resin, a polyimide resin, and/or the like. According to some embodiments, the pixel defining layers PDL may each include a light absorbing material or may be coated with a light absorbing agent to absorb light introduced from the outside. For example, the pixel defining layers PDL may each include a carbon-based black pigment, but are not limited thereto.

The pixel defining layers PDL may protrude in the third direction DR3 from a surface (e.g., an upper surface) of the circuit element layer PCL.

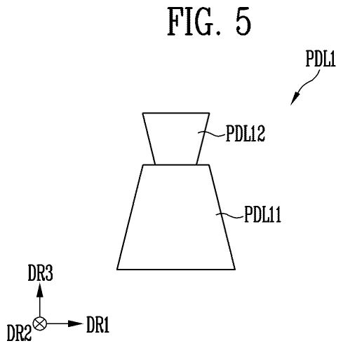

Each of first pixel defining layers PDL1 and each of second pixel defining layers PDL2 may have different shapes from each other. This will be described further below with reference to FIG. 5.

Hereinafter, at least one of the first pixel defining layers may be referred to as a “first pixel defining layer PDL1”, or two or more of the first pixel defining layers may be collectively referred to as the “first pixel defining layer PDL1” or “first pixel defining layers PDL1”. Likewise, at least one of the second pixel defining layers may be referred to as a “second pixel defining layer PDL2”, or two or more of the first pixel defining layers may be collectively referred to as the “second pixel defining layer PDL2” or “second pixel defining layers PDL2”.

As illustrated in FIG. 4, regions where the first and second light emitting regions EA1 and EA2 are located may be respectively defined by the first pixel defining layer PDL1 and the second pixel defining layer PDL2. In addition, a region where the non-light emitting region NEA is located may be defined by another first pixel defining layer PDL1 and the second pixel defining layer PDL2.

The lower electrode layer BE may be formed on a surface of the circuit element layer PCL that is not covered by the pixel defining layers PDL. For example, the lower electrode layer BE may be formed on a surface of the circuit element layer PCL that is not covered by the pixel defining layers PDL in the first light emitting region EA1, the non-light emitting region NEA, and the second light emitting region EA2. The lower electrode layer BE may be an electrode layer to which the second power supply voltage ELVSS is supplied by the power supply 150.

The light sensing element PD may be disposed on the lower electrode layer BE in the first light emitting region EA1. The light sensing element PD may include an anode electrode, a cathode electrode, and a photoelectric conversion layer interposed therebetween. The light sensing element PD may be a photoelectric conversion element that converts externally incident light into an electrical signal. The light sensing element PD may be, for example, a p-n-type or pin-type photo-diode, or a photo-transistor. The photo-diode may be an organic photo-diode using an organic material, but is not limited thereto, and may also be an inorganic photo-diode formed of an inorganic material.

The intermediate electrode layer ME may be disposed on the light sensing element PD, the lower electrode layer BE, and the pixel defining layers PDL. For example, as illustrated in FIG. 4, the intermediate electrode layer ME may be disposed on a part of the first pixel defining layer PDL1, the second pixel defining layer PDL2, the light sensing element PD, and the lower electrode layer BE.

A first intermediate electrode layer ME1 may be disposed in the first light emitting region EA1 and the non-light emitting region NEA.

In addition, a second intermediate electrode layer ME2 may be disposed in the second light emitting region EA2 and the non-light emitting region NEA.

The first and second intermediate electrode layers ME1 and ME2 disposed on different sub-pixels may be physically separated by the first pixel defining layer PDL1. For example, the first intermediate electrode layer ME1 may be physically separated from the second intermediate electrode layer ME2 by the first pixel defining layer PDL1. As illustrated in FIG. 4, the first intermediate electrode layer ME1 or the second intermediate electrode layer ME2 may not be disposed on a part of the first pixel defining layer PDL1 due to a shape of the first pixel defining layer PDL1. Due to this, the first intermediate electrode layer ME1 may be physically separated from the second intermediate electrode layer ME2 by the first pixel defining layer PDL1.

The first voltage V1 may be supplied to the intermediate electrode layer ME by the power supply 150.

Light emitting elements may be arranged on the intermediate electrode layer ME. For example, the first hole transfer layer HTL1, the first light emission layer EML1, and the first electron transfer layer ETL1 may be sequentially deposited on the first intermediate electrode layer ME1 in the first emission region EA1. For example, the second hole transfer layer HTL2, the second light emitting layer EML2, and the second electron transfer layer ETL2 may be sequentially deposited on the second intermediate electrode layer ME2 in the second light emitting region EA2.

The first hole transfer layer HTL1 may supply holes to the first light emitting layer EML1, and the first electron transfer layer ETL1 may supply electrons to the first light emitting layer EML1. Light may be emitted from the first light emitting layer EML1 through the combination of electrons and holes.

The second hole transfer layer HTL2 may supply holes to the second light emitting layer EML2, and the second electron transfer layer ETL2 may supply electrons to the second light emitting layer EML2. Light may be emitted from the second light emitting layer EML2 through the combination of electrons and holes.

The first light emitting element EL1 and the light sensing element PD may overlap each other in the third direction DR3.

The upper electrode layer TE may be disposed on the first and second electron transfer layers ETL1 and ETL2 and the pixel defining layers PDL. For example, as illustrated in FIG. 4, the upper electrode layer TE may be disposed on a part of the first pixel defining layer PDL1, the second pixel defining layer PDL2, and the first and second electron transfer layers ETL1 and ETL2.

The first upper electrode layer TE1 may be disposed in the first light emitting region EA1 and the non-light emitting region NEA.

In addition, the second upper electrode layer TE2 may be disposed in the second light emitting region EA2 and the non-light emitting region NEA.

The upper electrode layers TE disposed on different sub-pixels may be physically separated by the first pixel defining layer PDL1. For example, the first upper electrode layer TE1 may be physically separated from the second upper electrode layer TE2 by the first pixel defining layer PDL1. As illustrated in FIG. 4, the first upper electrode layer TE1 or the second upper electrode layer TE2 may not be disposed on a part of the first pixel defining layer PDL1 due to a shape of the first pixel defining layer PDL1. As a result, the first upper electrode layer TE1 may be physically separated from the second upper electrode layer TE2 by the first pixel defining layer PDL1.

The first power supply voltage ELVDD may be supplied to the upper electrode layer TE by the power supply 150.

In some embodiments of the present disclosure, the power supply 150 may adjust a level of the first voltage V1 in response to the fourth control signal PCS. When a level of the first voltage V1 is changed, a voltage difference between the first voltage V1 and the first power supply voltage ELVDD may be changed. In other words, a voltage difference across both ends of each of light emitting elements (e.g., the first light emitting element EL1, the second light emitting element EL2, and/or the like) may be changed. Due to this, whether the light emitting elements are driven may be determined (e.g., identified).

In addition, when the level of the first voltage V1 is changed, a voltage difference between the first voltage V1 and the second power supply voltage ELVSS may be changed. In other words, a voltage difference between both ends of the light sensing element PD may be changed. Due to this, whether the light sensing element PD is driven may be determined.

In some embodiments of the present disclosure, the display device DD may individually drive the first light emitting element EL1 and the light sensing element PD by adjusting a level of the first voltage V1. For example, while the first to third light emitting elements EL1 to EL3 emit light, the light sensing element PD may not be driven. For example, while the first to third light emitting elements EL1 to EL3 are not driven, the light sensing element PD may detect a touch on the display panel DP or recognize a fingerprint on the display panel DP.

The upper auxiliary electrode layer TAE may be disposed on the upper electrode layer TE. The upper auxiliary electrode layer TAE may be disposed in the entire regions of the first light emitting region EA1, the non-light emitting region NEA, and the second light emitting region EA2. In other words, the upper auxiliary electrode layer TAE disposed on the first light emitting region EA1 and the upper auxiliary electrode layer TAE disposed on the second light emitting region EA2 may not be physically separated from each other by the first pixel defining layer PDL1. In other words, the upper auxiliary electrode layer TAE disposed on the first light emitting region EA1 may be electrically connected to the upper auxiliary electrode layer TAE disposed on the second light emitting region EA2.

The encapsulation layer TFE may be disposed on the upper auxiliary electrode layer TAE. The encapsulation layer TFE may prevent external moisture and oxygen from penetrating into the upper auxiliary electrode layer TAE, or substantially reduce the likelihood thereof.

The touch sensing panel TSP may be placed on the encapsulation layer TFE.

The touch sensing panel TSP may obtain information on a touch input when the touch input is received from a user. The touch sensing panel TSP may recognize the touch input by using a capacitive sensing method. The touch sensing panel TSP may detect the touch input by using a mutual capacitance method or a self-capacitance method.

A window may be placed on the touch sensing panel TSP. The window may be a transparent light-transmitting substrate. The window and the touch sensing panel TSP may be coupled to each other through an optically transparent adhesive member. The window may transmit visual information therethrough while reducing external impact on the display device DD. For example, the window may be formed of rigid glass, flexible plastic, or so on the like. However, embodiments of the present disclosure are not limited thereto.

FIG. 5 is a view illustrating the first pixel defining layer of FIG. 4, according to some embodiments of the present disclosure.

Referring to FIG. 5, the first pixel defining layer PDL1 may include an eleventh pixel defining layer PDL11 and a twelfth pixel defining layer PDL12 coupled to each other in the third direction DR3.

The eleventh pixel defining layer PDL11 may have substantially the same shape as the second pixel defining layer PDL2. The eleventh pixel defining layer PDL11 may have a shape of which cross-section is gradually reduced in the third direction DR3. For example, the eleventh pixel defining layer PDL11 may have the cross-section of trapezoidal shape.

In addition, the twelfth pixel defining layer PDL12 may have a shape of which cross-section is gradually increased in the third direction DR3. For example, the twelfth pixel defining layer PDL12 may have a cross-section of an inverted trapezoidal shape.

A material may not be deposited on a partial region of the twelfth pixel defining layer PDL12 during a deposition process due to a shape of the twelfth pixel defining layer PDL12. By using this, the first intermediate electrode layer ME1 may be physically separated from the second intermediate electrode layer ME2 by the first pixel defining layer PDL1 as illustrated in FIG. 4. Likewise, by using this, the first upper electrode layer TE1 may be physically separated from the second upper electrode layer TE2 by the first pixel defining layer PDL1 as illustrated in FIG. 4.

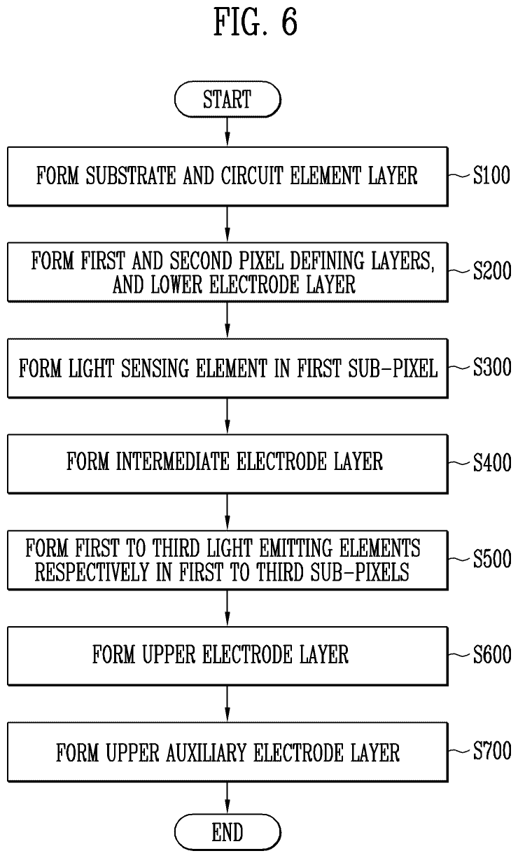

FIG. 6 is a flowchart illustrating a method of manufacturing a display device according to some embodiments of the present disclosure.

Referring to FIGS. 1 to 6, the substrate SUB and the circuit element layer PCL may be formed in process S100.

The first and second pixel defining layers PDL1 and PDL2 and the lower electrode layer BE may be formed on the circuit element layer PCL (S200).

The light sensing element PD may be formed on the lower electrode layer BE of the first sub-pixel SPXL1 (S300).

The intermediate electrode layer ME may be formed (S400).

The first, second, and third light emitting elements EL1, EL2, and EL3 may be respectively formed on the first, second, and third sub-pixels SPXL1, SPXL2, and SPXL3 (S500). For example, the first light emitting element EL1 may be formed on the first sub-pixel SPXL1. The second light emitting element EL2 may be formed in the second sub-pixel SPXL2. The third light emitting element EL3 may be formed in the third sub-pixel SPXL3.

The upper electrode layer TE may be formed (S600).

The upper auxiliary electrode layer TAE may be formed (S700).

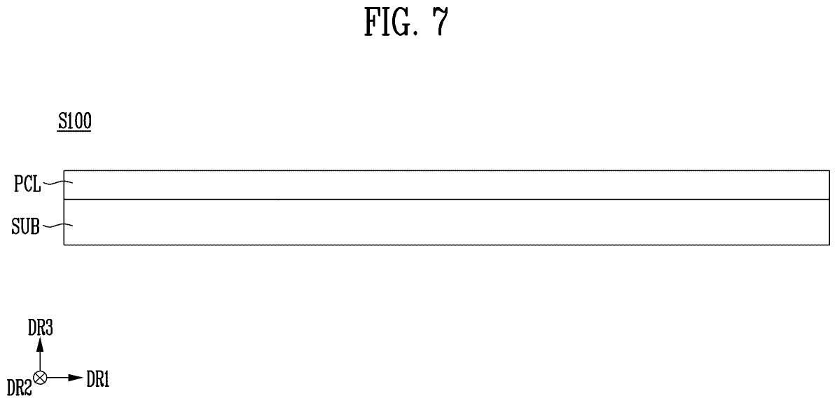

FIG. 7 is a view illustrating the process (S100) of forming the substrate and the circuit element layer as described in FIG. 6, according to some embodiments of the present disclosure.

Referring to FIGS. 1 to 7, the substrate SUB and the circuit element layer PCL may be formed (S100).

The substrate SUB may include a semiconductor substrate. For example, the substrate SUB may include a silicon bulk wafer or an epitaxial wafer. The epitaxial wafer may include a crystalline material layer, that is, an epitaxial layer, grown on a bulk substrate through an epitaxial process. The substrate SUB may be formed by using various wafers, such as a polished wafer, an annealed wafer, and a silicon on insulator (SOI) wafer without being limited to the silicon bulk wafer or an epitaxial wafer.

The circuit element layer PCL may be disposed on the substrate SUB. The circuit element layer PCL may include the first to third light emitting elements EL1 to EL3, circuit elements for driving the light sensing element PD, and at least one insulating layer between the circuit elements. The circuit elements may include a plurality of transistors and signal lines connected to the plurality of transistors. For example, the transistors may each be a MOSFET but are not limited thereto. In addition, the circuit elements may each include a gate electrode, source/drain regions, and a channel region.

The substrate SUB and the circuit element layer PCL may be formed by using a semiconductor process and equipment but are not limited thereto.

The substrate SUB and the circuit element layer PCL may be formed in the first to third sub-circuit elements SPXL1 to SPXL3 and the non-emitting region NEA.

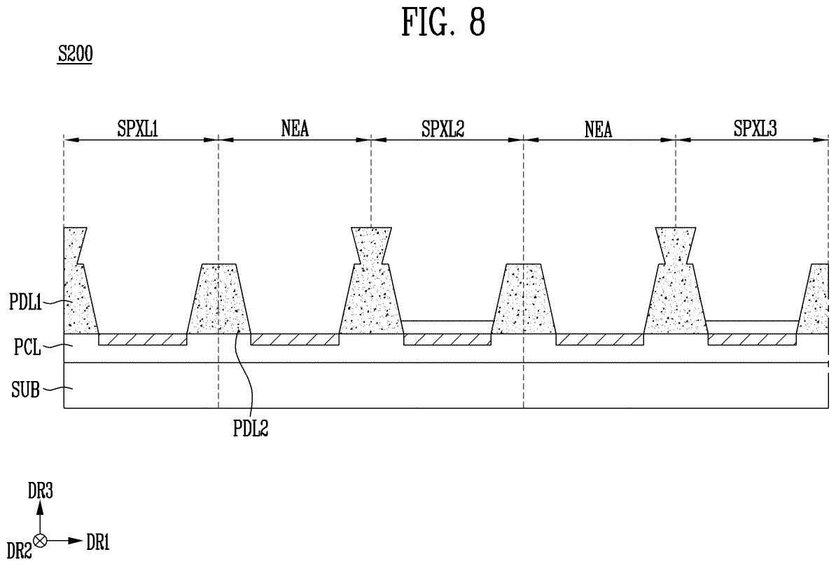

FIG. 8 is a view illustrating the process (S200) of forming the first and second pixel defining layers and lower electrode layer as described with reference to FIG. 6, according to some embodiments of the present disclosure.

Referring to FIGS. 1 to 8, the pixel defining layers PDL and the lower electrode layer BE may be formed on the circuit element layer PCL.

The pixel defining layers PDL may be composed of an organic insulating layer including an organic material. The organic material may include an acrylic resin, an epoxy resin, a phenolic resin, a polyamide resin, a polyimide resin, and/or the like. According to some embodiments, the pixel defining layers PDL may each include a light absorbing material or may be coated with a light absorbing agent to absorb light introduced from the outside. For example, the pixel defining layers PDL may each include a carbon-based black pigment, but are not limited thereto.

The pixel defining layers PDL may protrude in the third direction DR3 from a surface (or an upper surface) of the circuit element layer PCL.

As illustrated in FIG. 8, regions where the first to third sub-pixels SPXL1 to SPXL3 are located may be defined by the first pixel defining layer PDL1 and the second pixel defining layer PDL2. In addition, a region where the non-light emitting region NEA is located may be defined by the first pixel defining layer PDL1 and the second pixel defining layer PDL2.

The lower electrode layer BE may be formed on a surface of the circuit element layer PCL that is not covered by the pixel defining layers PDL. The lower electrode layer BE may be an electrode layer to which the second power supply voltage ELVSS is supplied by the power supply 150.

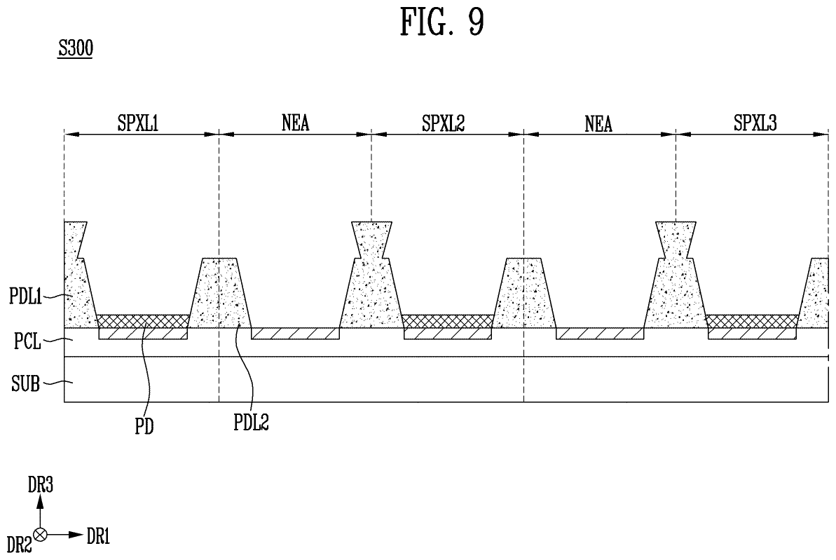

FIG. 9 is a view illustrating the process (S300) of forming a light sensing element as described with reference to FIG. 6, according to some embodiments of the present disclosure.

Referring to FIGS. 1 to 9, in the first light emitting region EA1, the light sensing element PD may be disposed on the lower electrode layer BE. The light sensing element PD may include an anode electrode, a cathode electrode, and a photoelectric conversion layer interposed therebetween. The light sensing element PD may be a photoelectric conversion element that converts externally incident light into an electrical signal. The light sensing element PD may be, for example, a p-n-type or pin-type photo-diode, or a photo-transistor. The photo-diode may be an organic photo-diode using an organic material, but is not limited thereto, and may also be an inorganic photo-diode formed of an inorganic material.

In some embodiments of the present disclosure, the light sensing element PD may be disposed in only one of the first to third sub-pixels SPXL1 to SPXL3. Although FIG. 9 illustrates that the light sensing element PD is disposed in only the first sub-pixel SPXL1, but embodiments of the present disclosure are not limited thereto.

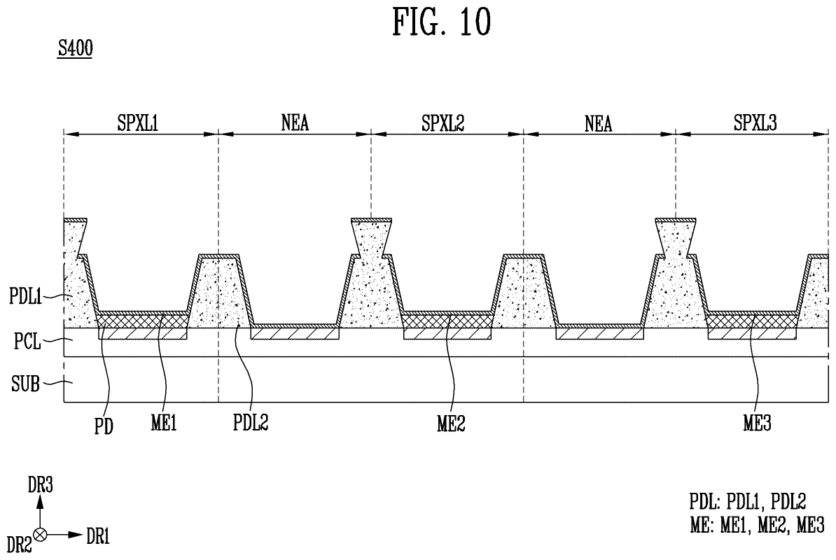

FIG. 10 is a view illustrating the process (S400) of forming an intermediate layer as described with reference to FIG. 6, according to some embodiments of the present disclosure.

Referring to FIGS. 1 to 10, the intermediate electrode layer ME may be disposed on the light sensing element PD, the lower electrode layer BE, and the pixel defining layers (PDL). For example, as illustrated in FIG. 4, the intermediate electrode layer ME may be disposed on a part of the first pixel defining layer PDL1, the second pixel defining layer PDL2, the light sensing element PD, and the lower electrode layer BE.

The intermediate electrode layer ME may include the first, second, and third intermediate electrode layers ME1, ME2, and ME3.

The first intermediate electrode layer ME1 may be disposed in the first light emitting region EA1 (or the first sub-pixel SPXL1) and the non-light emitting region NEA. In addition, the second intermediate electrode layer ME2 may be disposed in the second light emitting region EA2 (or the second sub-pixel SPXL2) and the non-light emitting region NEA. The third intermediate electrode layer ME3 may be disposed in the third light emitting region EA3 (or the third sub-pixel SPXL3) and the non-light emitting region NEA.

The intermediate electrode layers ME disposed on different sub-pixels may be physically separated from each other by the first pixel defining layer PDL1.

The first intermediate electrode layer ME1 may be physically separated from and the second intermediate electrode layer ME2 by the first pixel defining layer PDL1. As illustrated in FIG. 10, the first intermediate electrode layer ME1 or the second intermediate electrode layer ME2 may not be disposed on a partial region of the first pixel defining layer PDL1 due to a shape of the first pixel defining layer PDL1. Due to this, the first intermediate electrode layer ME1 may be physically separated from the second intermediate electrode layer ME2 by the first pixel defining layer PDL1.

Likewise, the second intermediate electrode layer ME2 may be physically separated from the third intermediate electrode layer ME3 by the first pixel defining layer PDL1. As illustrated in FIG. 10, the second intermediate electrode layer ME2 or the third intermediate electrode layer ME3 may not be disposed on a partial region of the first pixel defining layer PDL1 due to a shape of the first pixel defining layer PDL1. As a result, the second intermediate electrode layer ME2 may be physically separated from the third intermediate electrode layer ME3 by the first pixel defining layer PDL1.

The first voltage V1 may be supplied to the intermediate electrode layer ME by the power supply 150.

FIG. 11 is a view illustrating the process (S500) of forming the first to third light emitting elements as described with reference to FIG. 6, according to some embodiments of the present disclosure.

Referring to FIGS. 1 to 11, light emitting elements may be disposed on the intermediate electrode layer ME. For example, the first hole transfer layer HTL1, the first light emission layer EML1, and the first electron transfer layer ETL1 may be sequentially deposited on the first intermediate electrode layer ME1 in the first emission region EA1. For example, the second hole transfer layer HTL2, the second light emitting layer EML2, and the second electron transfer layer ETL2 may be sequentially deposited on the second intermediate electrode layer ME2 in the second light emitting region EA2. A third hole transfer layer HTL3, a third light emitting layer EML3, and a third electron transfer layer ETL3 may be sequentially deposited on the third intermediate electrode layer ME3 in the third light emitting region EA3.

The first hole transfer layer HTL1 may supply holes to the first light emitting layer EML1, and the first electron transfer layer ETL1 may supply electrons to the first light emitting layer EML1. Light may be emitted from the first light emitting layer EML1 through the combination of electrons and holes.

The second hole transfer layer HTL2 may supply holes to the second light emitting layer EML2, and the second electron transfer layer ETL2 may supply electrons to the second light emitting layer EML2. Light may be emitted from the second light emitting layer EML2 through the combination of electrons and holes.

The third hole transfer layer HTL3 may supply holes to the third light emitting layer EML3, and the third electron transfer layer ETL3 may supply electrons to the third light emitting layer EML3. Light may be emitted from the third light emitting layer EML3 through the combination of electrons and holes.

FIG. 12 is a view illustrating the process (S600) of forming the upper electrode layer as described with reference to FIG. 6, according to some embodiments of the present disclosure.

Referring to FIGS. 1 to 12, the upper electrode layer TE may be disposed on the first to third electron transfer layers ETL1 to ETL3 and the pixel defining layers PDL. For example, as illustrated in FIG. 4, the upper electrode layer TE may be disposed on a partial region of the first pixel defining layer PDL1, the second pixel defining layer PDL2, and the first to third electron transfer layers ETL1 to ETL3.

The first upper electrode layer TE1 may be disposed in the first light emitting region EA1 (or the first sub-pixel SPXL1) and the non-light emitting region NEA.

In addition, the second upper electrode layer TE2 may be disposed in the second light emitting region EA2 (or the second sub-pixel SPXL2) and the non-light emitting region NEA.

In addition, the third upper electrode layer TE3 may be disposed in the third light emitting region EA3 (or the third sub-pixel SPXL3) and the non-light emitting region NEA.

The upper electrode layers TE disposed on different sub-pixels may be physically separated from each other by the first pixel-defining layer PDL1.

The first upper electrode layer TE1 may be physically separated from the second upper electrode layer TE2 by the first pixel-defining layer PDL1. As illustrated in FIG. 12, the first upper electrode layer TE1 or the second upper electrode layer TE2 may not be disposed on a partial region of the first pixel defining layer PDL1 due to a shape of the first pixel defining layer PDL1. As a result, the first upper electrode layer TE1 may be physically separated from the second upper electrode layer TE2 by the first pixel defining layer PDL1.

Likewise, the second upper electrode layer TE2 may be physically separated from the third upper electrode layer TE3 by the first pixel defining layer PDL1. As illustrated in FIG. 12, the second upper electrode layer TE2 or the third upper electrode layer TE3 may not be disposed on a partial region of the first pixel defining layer PDL1 due to a shape of the first pixel defining layer PDL1. Due to this, the second upper electrode layer TE2 may be physically separated from the third upper electrode layer TE3 by the first pixel defining layer PDL1.

The first power supply voltage ELVDD may be supplied to the upper electrode layer TE by the power supply 150.

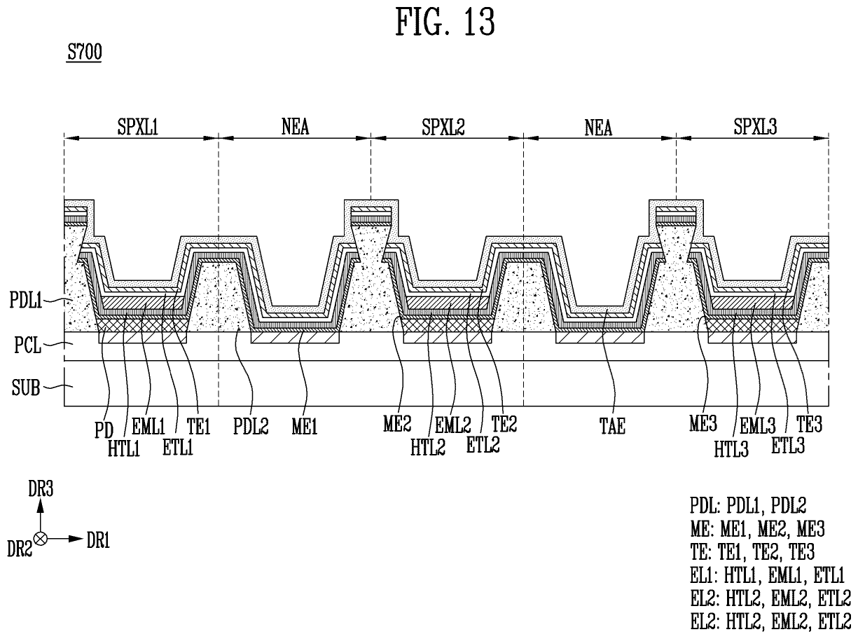

FIG. 13 is a view illustrating the process (S700) of forming the upper auxiliary electrode layer as described with reference to FIG. 6, according to some embodiments of the present disclosure.

Referring to FIGS. 1 to 13, the upper auxiliary electrode layer TAE may be disposed on the upper electrode layer TE. The upper auxiliary electrode layer TAE may be disposed in the entire regions of the first to third sub-pixels SPXL1 to SPXL3 and the non-emitting region NEA. In other words, the upper auxiliary electrode layers TAE disposed on different sub-pixels may not be physically separated from each other by the first pixel defining layer PDL1.

A display device according to some embodiments is applicable to various types of electronic devices. In some embodiments, an electronic device includes the above-described display device and may further include other modules or devices having additional functions in addition to the display device.

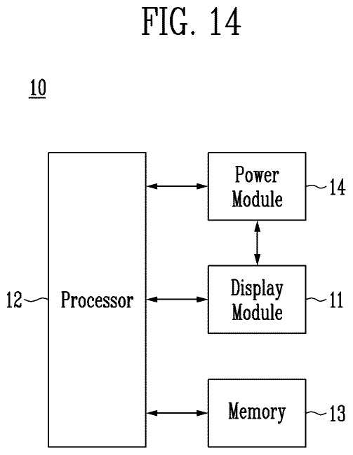

FIG. 14 is a block diagram of an electronic device according to some embodiments of the present disclosure. Referring to FIG. 14, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

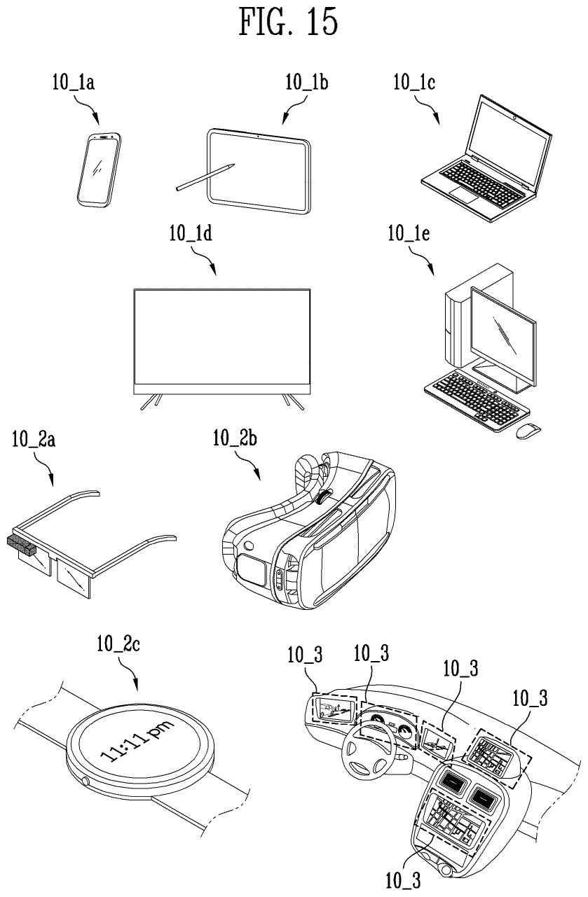

FIG. 15 shows schematic views of various embodiments of an electronic device, according to some embodiments of the present disclosure.

Referring to FIG. 15, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate comprising a region where a first sub-pixel and a second sub-pixel are formed;
a lower electrode layer on the substrate;
a light sensing element on the lower electrode layer of the first sub-pixel;
a first intermediate electrode layer on the light sensing element;
a first light emitting element on the first intermediate electrode layer; and
a first upper electrode layer on the first light emitting element,
wherein the first light emitting element and the light sensing element are individually driven according to a voltage applied to the first intermediate electrode layer.

2. The display device of claim 1, wherein the light sensing element is not driven in a period in which the first light emitting element emits light.

3. The display device of claim 1, further comprising:
a second intermediate electrode layer on the lower electrode layer of the second sub-pixel;
a second light emitting element on the second intermediate electrode layer; and
a second upper electrode layer on the second light emitting element,
wherein the second light emitting element emits different light from the first light emitting element.

4. The display device of claim 3, further comprising:
first pixel defining layers and second pixel defining layers on the substrate and protruding in a direction perpendicular to the substrate,
wherein the first intermediate electrode layer is physically separated from the second intermediate electrode layer by the first pixel defining layers, and
wherein the first upper electrode layer is physically separated from the second upper electrode layer by the first pixel defining layers.

5. The display device of claim 4, wherein the first pixel defining layers have different shapes from the second pixel defining layers.

6. The display device of claim 4, wherein each of the second pixel defining layers has a cross-section of a trapezoidal shape.

7. The display device of claim 4, wherein each of the first pixel defining layers has an eleventh pixel defining layer and a twelfth pixel defining layer coupled to each other in a form perpendicular to the substrate,
wherein the eleventh pixel defining layer has a cross-section of a trapezoidal shape, and
wherein the twelfth pixel defining layer has a cross-section of an inverted trapezoidal shape.

8. The display device of claim 4, further comprising:
upper auxiliary electrode layers on the first upper electrode layer and the second upper electrode layer,
wherein the upper auxiliary electrode layer on the first upper electrode layer is physically connected to the upper auxiliary electrode layer on the second upper electrode layer.

9. The display device of claim 4, wherein a second power supply voltage is applied to the lower electrode layer,
wherein a first power supply voltage is applied to each of the first upper electrode layer and the second upper electrode layer, and
wherein a level of the first power supply voltage is higher than a level of the second power supply voltage.

10. An electronic device comprising the display device of claim 1.

11. The electronic device of claim 10, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

12. A method of manufacturing a display device, the method comprising:
forming a substrate comprising a region where a first sub-pixel and a second sub-pixel are formed;
forming a lower electrode layer on the substrate;
forming a light sensing element on the lower electrode layer of the first sub-pixel;
forming a first intermediate electrode layer on the light sensing element;
forming a first light emitting element on the first intermediate electrode layer; and
forming a first upper electrode layer on the first light emitting element,
wherein the first light emitting element and the light sensing element are individually driven according to a voltage applied to the first intermediate electrode layer.

13. The method of claim 12, wherein the light sensing element is not driven in a period in which the first light emitting element emits light.

14. The method of claim 12, further comprising:
forming a second intermediate electrode layer on the lower electrode layer of the second sub-pixel;
forming a second light emitting element on the second intermediate electrode layer; and
forming a second upper electrode layer on the second light emitting element.

15. The method of claim 14, further comprising:
forming, on the substrate, first pixel defining layers and second pixel defining layers protruding in a direction perpendicular to the substrate,
wherein the first intermediate electrode layer is physically separated from the second intermediate electrode layer by the first pixel defining layers, and
wherein the first upper electrode layer is physically separated from the second upper electrode layer by the first pixel defining layers.

16. The method of claim 15, wherein the first pixel defining layers have different shapes from the second pixel defining layers.

17. The method of claim 15, wherein each of the second pixel defining layers has a cross-section of a trapezoidal shape.

18. The method of claim 15, wherein each of the first pixel defining layers has an eleventh pixel defining layer and a twelfth pixel defining layer coupled to each other in a form perpendicular to the substrate,
wherein the eleventh pixel defining layer has a cross-section of a trapezoidal shape, and
wherein the twelfth pixel defining layer has a cross-section of an inverted trapezoidal shape.

19. The method of claim 15, further comprising:
forming upper auxiliary electrode layers respectively on the first upper electrode layer and the second upper electrode layer,
wherein the upper auxiliary electrode layer on the first upper electrode layer is physically connected to the upper auxiliary electrode layer on the second upper electrode layer.

20. The method of claim 15, wherein a second power supply voltage is applied to the lower electrode layer,
wherein a first power supply voltage is applied to each of the first upper electrode layer and the second upper electrode layer, and
wherein a level of the first power supply voltage is higher than a level of the second power supply voltage.
